(19) United States
(12) Patent Application Publication
(10) Pub. No.: US 2009/0269939 A1
(43) Pub. Date: Oct. 29, 2009

(54) CYCLICAL OXIDATION PROCESS

(75) Inventor: Hessel Sprey, Kessel-Lo (BE)

Correspondence Address: KNOBBE MARTENS OLSON & BEAR LLP, 2040 MAIN STREET, FOURTEENTH FLOOR, IRVINE, CA, 92614, US

(73) Assignee: ASM International, N.V., Almere (NE)

(21) Appl. No.: 12/395,443

(22) Filed: Feb. 27, 2009

Related U.S. Application Data
(60) Provisional application No. 61/048,101, filed on Apr. 25, 2008.

(51) Int. Cl. H01L 21/316; H01L 21/31

(52) U.S. Cl. 438/773; 257/E21.24; 257/E21.274

(57) ABSTRACT

Methods for selective oxidation using pulses of an oxidizing agent are described. An oxidation process is provided in which a pulse of an oxidizing agent is followed by a flow of a purging agent. The pulse of the oxidizing agent and the flow of the purging agent forms a cycle that can be repeated to allow for desired oxidation on parts of a structure, e.g., a transistor structure, while preventing or limiting undesired oxidation on other parts of the structure. In addition, during the oxidation, a nitrogen source such as N₂, NH₃, N₂H₄ or combinations thereof, can be provided to enhance the selectivity of the oxidation process. The nitrogen source can act as an oxygen scavenger to enhance oxidation selectively, or undesired oxidation can also be further prevented or limited by introducing other oxygen scavengers, such as hydrazine.

The present application claims priority under 35 U.S.C. §119(e) to U.S. Provisional Patent Application Ser. No. 61/048,101, entitled “Cyclical Oxidation Process,” filed Apr. 25, 2008. The entire disclosure of the priority application is hereby incorporated by reference in its entirety.

### BACKGROUND OF THE INVENTION

1. Field of the Invention

This application relates to methods of cyclical oxidation for integrated circuit components.

2. Description of the Related Art

Semiconductor device fabrication is a complex process. Devices are typically formed on a semiconductor substrate, and often include conductive elements separated by insulating elements. Conductive elements may serve as electrodes and interconnecting conductors, and may be formed from materials such as polysilicon, metal or metallic compounds.

Various transistor devices exist in the modern day fabrication of integrated circuits, including metal-oxide-semiconductor field-effect transistors, or MOSFETs. A MOSFET generally comprises a conductive gate electrode formed over a gate dielectric, which in turn overlies a semiconductor substrate. For reliable MOSFET performance, it is important to maintain the conductivity of the gate electrode stack, which may include silicon or metallic materials, such as tungsten or titanium, to set the transistor work function and strapping layers for high speed lateral signal transmission.

Common transistor devices which may incorporate MOSFETs include memory devices used for data storage. These memory devices may be categorized, in general, as being either volatile or non-volatile. Volatile memory devices include dynamic random access memory devices (DRAM) and static random access memory devices (SRAM), and lose their stored data when power supplies are interrupted. In contrast, non-volatile memory devices include electrically erasable programmable read only memory (EEPROM) devices and flash memory devices, and retain their stored data even when power supplies are interrupted, and are thus commonly used in memory cards and mobile telecommunication systems.

An example of a non-volatile memory device is a floating gate memory a field effect device which allows electric charges to be stored on an isolated conductive material referred to as a “floating gate.” A typical floating gate memory device includes a floating gate, often comprising polysilicon, and a control gate, typically comprising a metal such as titanium or tungsten, above the floating gate in a gate stack. The gate stack may further include a “tunnel” dielectric layer (composed of, for example, silicon oxide) beneath the floating gate, which serves to electrically isolate and control charge injection to the floating gate from a silicon substrate. The floating gate may also be electrically isolated from the control gate by an intergate dielectric layer, such as an oxide-nitride-oxide (ONO) layer.

To achieve a transistor device with desirable characteristics, oxidation must often be performed on certain components in a semiconductor device. For example, an oxidation process is often used to repair damaged areas caused during etching to pattern the gate stack. Such oxidation, however, can undesirably change the properties of the transistor device.

Accordingly, there is a need for oxidation processes that do not significantly alter the properties of the electronic devices that are oxidized.

### SUMMARY

The present application provides methods for cyclical oxidation of integrated circuit components. In some embodiments, a method of selective oxidation comprises providing a transistor structure having exposed silicon and metal, wherein the transistor structure comprises a patterned gate stack having a gate electrode and a dielectric layer. A pulse of an oxidizing agent is introduced to the transistor structure, such that the silicon is oxidized relative to the metal. The oxidizing agent is then purged. The steps of introducing a pulse of an oxidizing agent and purging are repeated.

In some embodiments, a method of performing oxidation comprises providing a patterned transistor gate stack. A pulse of an oxidizing agent is introduced to the patterned transistor gate stack. The oxidizing agent is purged for a duration between three and fifteen times the duration of the pulse of the oxidizing agent. The steps of introducing a pulse of an oxidizing agent and purging are repeated.

In some embodiments, a method of performing oxidation comprises providing a transistor gate stack on a substrate in a processing chamber. In the chamber, a plurality of oxidation cycles are performed, each cycle comprising introducing an oxidizing agent into the processing chamber to oxidize at least some portion of the gate stack, providing an oxygen scavenger in the processing chamber and removing the oxidizing agent from the processing chamber.

### BRIEF DESCRIPTION OF THE DRAWINGS

These and other features, aspects and advantages of the various devices, systems and methods presented herein are described with reference to drawings of certain embodiments, which are intended to illustrate, but not to limit, such devices, systems, and methods. The drawings include six figures. It is to be understood that the attached drawings are for the purpose of illustrating concepts of the embodiments discussed herein and may not be to scale.

FIG. 1A is a schematic, cross-sectional representation of a transistor structure comprising a patterned gate electrode stack having a gate oxide layer damaged by etching to pattern the stack.

FIG. 1B shows the transistor structure of FIG. 1A after undergoing an oxidation process.

FIG. 2 illustrates a transistor structure having a patterned gate stack according to one embodiment of the present application.

FIG. 3 is a flow chart illustrating a method of cyclic oxidation according to one embodiment of the present application.

FIG. 4 is a schematic, cross-sectional representation of a non-volatile memory device transistor structure having a control gate layer and a floating gate layer.

FIG. 5 shows a non-volatile memory device transistor structure having a patterned gate electrode structure having a control gate, a floating gate, and an intergate dielectric layer, in which areas prone to undesired oxide formation are identified, according to one embodiment of the present application.

FIG. 6 shows the non-volatile memory device transistor structure of FIG. 5 after a oxidation process according to one embodiment of the present application.

### DETAILED DESCRIPTION OF SOME EMBODIMENTS

It has been found that conditions during an oxidation of a transistor structure may result in undesired oxidation of certain areas of the structure. For example, undesired oxidation may occur on exposed metal-containing surfaces, which may result in increased resistance of a metal beyond useable levels. Diffusion of oxygen atoms or molecules, or water molecules (such as in the form of steam or moisture) across layers may also result in oxidation at unexposed interfacial regions within transistor devices, such as at the interface of a floating gate layer and ONO layer of a non-volatile memory device, which may also cause excessive thickening of the dielectric layers. If the dielectric is a high-k material, oxidation of the adjacent conductor can lower the effective k-value of the dielectric, and even silicon oxide layer performance is changed by thickening of the dielectric. It is difficult to reliably design for this thickening, due to differential diffusion from device-to-device and wafer-to-wafer, as well as the inherently differential effect of diffusion across the width of a gate stack.

The preferred embodiments provide methods of oxidation that prevent or limit undesired oxidation of parts of a structure, such as a transistor gate stack. The methods described herein relate generally to oxidation of transistor structures or other similar structures containing regions of different materials. In particular the methods relate to a cyclic oxidation process in which a cycle of a pulse of an oxidizing agent followed by a pulse of a purging agent is repeated to allow for desired oxidation of the exposed outer surface of the structures, while preventing or causing negligible oxidation at the interfaces between different regions within the structure. Without being limited by theory, the pulsed flow is believed to minimize undesired oxidation by interrupting oxidation before excessive oxidant diffusion into other areas of a transistor, such as interfacial regions, occurs. As a result, undesired oxidation of interfacial regions is prevented or limited, thereby preventing or limiting the changes in the properties of an electronic device caused by changes in the interfacial regions. In addition to being principally localized at the exposed outer surface of a structure, in some embodiments, the oxidation can be selective for some exposed materials relative to other exposed materials, which has advantages for preventing or limiting changes to the properties of those exposed materials.

In some embodiments, an oxygen scavenger may be provided in the processing chamber during the oxidation. The oxygen scavenger can assist with preventing undesired oxidation by reducing the number of oxidant atoms in the process chamber.

Advantageously, embodiments of the invention protect against oxidation in unexposed interfacial regions. In addition, some embodiments selectively oxidize some exposed material and limit oxidation on other exposed surfaces (e.g., metal-containing surfaces). An oxidation process that protects against undesired oxidation of a device helps to ensure the integrity of the devices.

Reference will now be made to the figures, in which like numerals refer to like parts throughout.

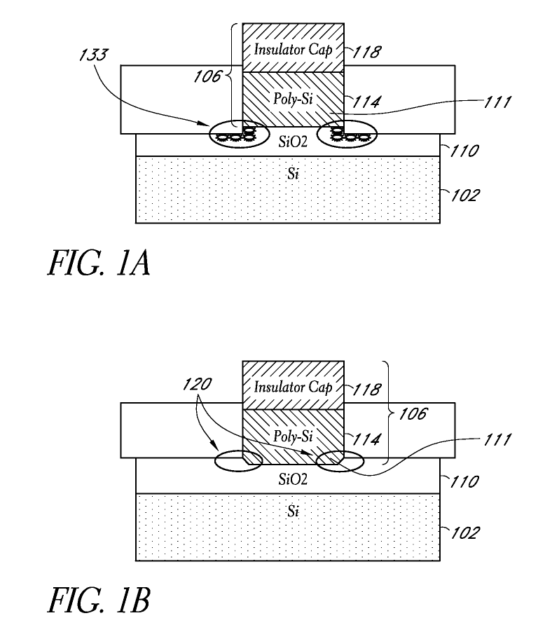

FIG. 1A is a cross-sectional representation of a transistor structure comprising a patterned gate electrode stack 106 according to one embodiment. The transistor structure comprises a patterned gate electrode stack 106 having a gate dielectric 110, a polysilicon gate 114 and an insulating cap 118, which can also serve as a hardmask, over a semiconductor substrate 102. The semiconductor substrate 102 is typically formed on or part of a silicon wafer, and is often composed of silicon. For some transistor designs, the gate electrode is metallic and/or additional metallic layers overlie the gate electrode.

The gate dielectric 110 formed over the substrate 102 can be an oxide, a high k material, or multi-layer combinations of different dielectric materials. In the embodiment illustrated in FIG. 1A, the gate dielectric 110 comprises silicon oxide or SiO₂. The gate dielectric 110 serves to prevent charge carriers in the channel in the substrate 102 from reaching the polysilicon gate 114. When the gate is switched on and field draws the charge carriers to the interface between the substrate 102 and the gate dielectric 110, the carriers gather at the interface to form a conductive path in the channel. Damage to the gate dielectric 110 and parts of the substrate 102 may occur during the etching process. As shown in FIG. 1A, such damage may result in areas of gate oxide thinning, such as at the lower gate corners 111, that may lead to undesired side effects, such as increased hot carrier injection, detrimental charge trapping effects 133 and electron leakage.

Such areas may need to be repaired by an oxidation process in order to preserve the integrity of the device. The oxidation process, often known as a “source/drain reoxidation,” may occur in a processing chamber. Such an oxidation process may take place after an etching process which has damaged one or more portions of the transistor gate structure.

FIG. 1B illustrates a cross-sectional representation of the transistor structure of FIG. 1A after undergoing an oxidation process. The oxidation process involves introducing an oxidizing agent to a transistor structure having a patterned gate stack 106, wherein a portion of the patterned gate stack 106 has been damaged (as shown in FIG. 1A).

As shown in FIG. 1B, the oxidation process can be used to repair multiple areas of the transistor structure. In particular, the oxidation process may repair damaged areas of the gate dielectric 110, including the areas of gate oxide thinning at the lower gate corners 111 shown in FIG. 1A. During the oxidation process, oxidation may also occur on the gate dielectric 110 and other layers of the transistor, including the sidewalls of the polysilicon gate 114. FIG. 1B illustrates oxidation resulting in the rounding of the bottom corners 111 of the polysilicon gate 114 to form “bird beaks” 120.

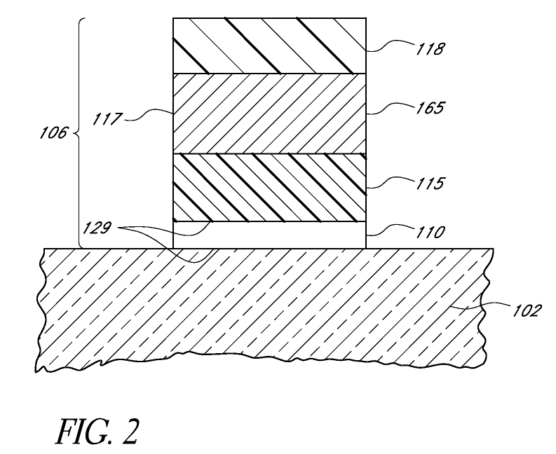

FIG. 2 illustrates a transistor structure having a patterned gate stack 106 which may benefit from oxidation according to one embodiment. The transistor structure includes a patterned gate stack 106 comprised of a gate dielectric 110, a gate electrode 115, a metallic strapping layer 165, and an insulator cap 118 above a silicon substrate 102. FIG. 2 also illustrates the exposed metallic sidewall 117 and interfacial regions 129, located at the interface of the gate dielectric 110 with the gate electrode 115 and with the substrate 102 within the transistor structure.

The gate electrode 115 is formed over the gate dielectric layer 110, and may be comprised of polysilicon, poly-SiGe, a metal, metal alloys, or metal compounds such as metal nitrides, metal carbides, or metal silicides. While traditional MOSFETs actually use silicon or silicon germanium as the “metal” gate electrode, more recently metallic materials have regained popularity due to higher conductivity, lower temperature processing availability, and the ability to finely tune composition to set work function. In some embodiments, the gate electrode 115 may comprise a metal such as titanium, tungsten, tantalum or other metal suitable as a conductive gate. In other embodiments, the gate electrode 115 may comprise a metal alloy or a metallic compound, wherein a portion of the layer may be comprised of one or more metals in combination with silicon, nitrogen, and/or carbon.

A metallic strapping layer 165 is formed over the gate electrode 115. The metallic strapping layer 165 helps to improve lateral signal speed across transmission lines. In some embodiments, the metallic strapping layer 165 comprises a metal such as Ta, W or Ti or a metal silicide. In other embodiments, the metallic strapping layer 165 may be comprised of a metallic alloy or compound, including but not limited to, TiNₓ, TaNₓ or WNₓ.

An insulating cap layer 118 (e.g., silicon oxide or nitride) is formed over the metal gate 115 and metallic strapping layer 165 to insulate the gate, and can serve as a hard mask to protect the gate stack during the etching process. Although only a single cap layer 118 is shown in FIG. 2, it is possible to have multiple layers, such as conductive barrier layers.

As will be appreciated by the skilled artisan, MOSFET devices can be established having gate, channel, source and drain regions, by diffusing or injecting appropriate dopants to selected regions. Other embodiments may include layers besides those shown in FIG. 2, including additional conductive or insulating layers.

In addition to the layers of the patterned gate stack 106, FIG. 2 also illustrates an exposed metal gate sidewall 117. During both selective and non-selective oxidation processes, oxidation may occur at the metal gate sidewall 117, detrimentally affecting the conductive properties of the transistor device. To protect the metal gate sidewall 117 from such undesired oxidation, it is possible to provide a passivation layer around the metal sidewall 117 (such as by nitridation), such that the metal sidewall 117 will have little or no oxidation during a selective oxidation process. Selective chemistries can also minimize oxidation of certain metals, relative to the rate of oxidation of silicon. An example of a selective oxidation chemistry involves dilute steam (H₂O) in hydrogen (H₂).

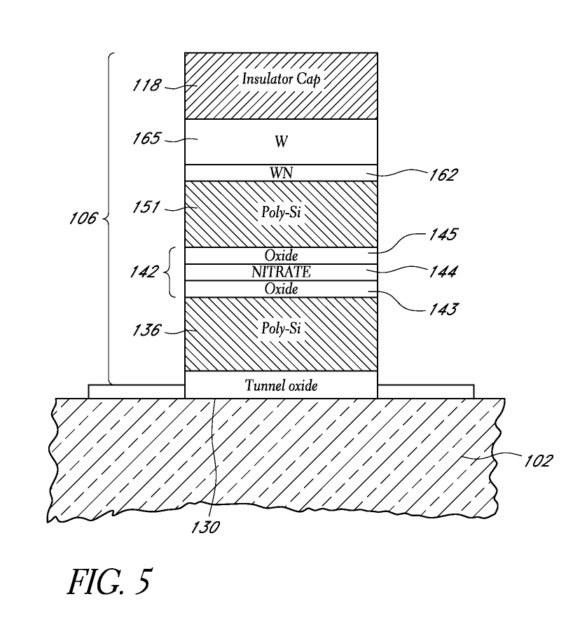

Like the exposed metal gate sidewall 117, unexposed areas of a transistor device may be subject to oxidation, including interfacial regions, due to diffusion during the oxidation process. FIG. 2 illustrates two interfacial regions 129, located between the gate dielectric 110 and the gate electrode 115, and between the gate dielectric 110 and the substrate 102. Other transistor devices, particularly those having even more layers than the transistor structure illustrated in FIG. 2, may have more than one interfacial region. Such interfacial regions may be located at the interface of a metal and semiconductor layer, a semiconductor and dielectric layer, a metal and dielectric layer, or other layer combinations. Interfaces that border on dielectrics are particularly subject to diffusion of oxidants. During an oxidation process, oxygen atoms or molecules, or water molecules, may diffuse through one or more layers to the interfaces, or along the interfaces themselves, resulting in oxidation and excessive oxide thickness increase (FIG. 5 illustrates several interfacial areas prone to undesired oxide formation in a flash gate stack) within transistor devices. Oxidation may be found across the entire width of an interfacial region, or the greatest oxidation may occur near the sidewalls of the layer and the least oxidation near the center of the layer.

In one embodiment, a method of cyclic oxidation is provided to reduce undesired oxidation at interfacial regions caused by diffusion. This cyclic oxidation process may benefit many different transistor structures, including the transistor structure shown in FIG. 2. In embodiments that have metal layers, the cyclic oxidation process may also be selective, such that layers containing minimal or no metal are oxidized relative to metal-containing layers, such that undesired oxidation of the metal-containing layers is prevented. For example, in one embodiment, a cyclic selective oxidation process will result in silicon containing layers of a transistor structure being selectively oxidized relative to metal containing layers of the transistor structure.

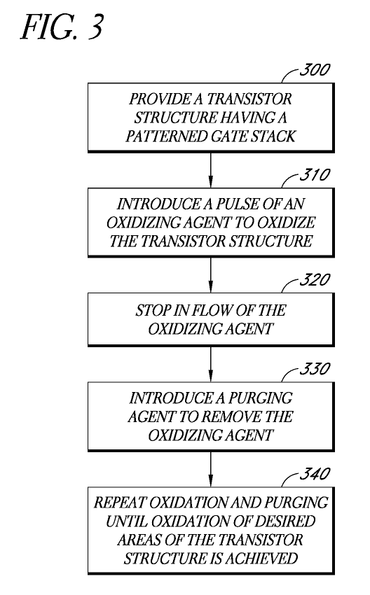

FIG. 3 is a flow chart illustrating a method of cyclic oxidation according to one embodiment of the present application. The method comprises providing 300 a transistor structure having a patterned gate stack, introducing 310 a pulse of an oxidizing agent to oxidize the transistor structure, stopping 320 the flow of the oxidizing agent, purging 330 to remove the oxidizing agent and repeating 340 the cycle of introducing the oxidizing agent and purging agent until selective oxidation of the transistor structure is achieved. Using an oxidation process that is cyclical (as opposed to non-cyclical) according to the present application allows for greater controllability of the overall oxidation process, such that oxidation caused by diffusion across the gate stack on metal-containing layers and interfacial oxidation within a gate stack may be reduced.

The cyclic oxidation processes described herein may be applicable to many transistor structures, including those having one or more patterned gate stacks of various designs. In some embodiments, a cyclic oxidation process that is selective may be used after providing 300 a transistor device whenever metal on the substrate should be protected from oxidation, whether or not the metal is in the same gate stack, although typically some layer in the gate stack includes exposed metal during the selective oxidation.

After providing 300 a transistor structure, in accordance with FIG. 3, a selective oxidation process may begin in which a pulse of an oxidizing agent is introduced 310 to the transistor structure. The term “pulse” is used herein to refer to the introduction 310 of an oxidizing agent (or purging agent) for a relatively short period of time, which depends in part on the diffusivity of oxidants along the interfaces. In some embodiments, the pulse of the oxidation agent will be introduced 310 for a duration between about 3 and about 300 seconds. In a preferred embodiment, a pulse of an oxidizing agent will have a duration between about 5 and about 30 seconds. In some embodiments, the oxidizing agent will be introduced 310 for a duration long enough to oxidize desired areas of a transistor gate structure, e.g., to repair damage under the gate corners, while at the same time, minimize oxidation in undesired areas of the transistor structure. The duration of oxidation may depend on a number of other factors which may include the type of oxidizing agent(s) used, as well as the temperature and pressure of the chamber during the oxidation process.

The oxidation may take place in a chamber having a temperature between about 550 and about 900° C., and more preferably between about 650 and about 850° C. In one embodiment, the oxidation takes place at about 750° C. Moreover, oxidation may take place in a chamber having a pressure of between about 1 and about 1000 Torr, more preferably between about 720 and about 780 Torr.

According to one embodiment in accordance with FIG. 3, the oxidation process includes introducing or pulsing 310 an oxidizing agent into a chamber for a specific duration. In one embodiment, the oxidizing agent comprises H₂O vapor, preferably introduced after beginning flow of H₂ to the process chamber. In embodiments that use H₂O vapor as the oxidizing agent, the oxidation may take place in a chamber having a H₂O water vapor concentration between about 0.0005% and about 40% by volume, as diluted in the hydrogen flow, with a higher H₂O water vapor pressure resulting in enhanced oxidation for some embodiments. In some embodiments, the H₂O water vapor concentration is between about 0.0005% and 20% by volume, as diluted in the hydrogen flow In a preferred embodiment, an oxidant mixture comprises between about 0.05% and about 5% by volume H₂O water vapor diluted in a hydrogen environment. The H₂O water vapor may be introduced at a flow rate between about 2 sccm and about 4 slm, and the H₂ may be introduced at a flow rate between about 5 and about 20 slm.

In some embodiments, after providing 300 a transistor structure and prior to introducing 310 a pulse of an oxidizing agent, a passivation layer may be created over metal-containing layers of the transistor structure to protect the layers from excess oxidation growth that may affect the conductive properties of the layers. In one embodiment, a passivation layer may be created by performing a nitridation process using a passivation agent such as nitrogen gas (N₂), ammonia gas (NH₃) or a mixture of pure nitrogen gas and ammonia gas, as described in U.S. Provisional Application 60/990,869, entitled “Protection of Titanium From Selective Oxidation of Silicon,” filed on Nov. 28, 2007, hereby incorporated by reference in its entirety. In embodiments wherein the oxidation process is selective, providing such a passivation layer can enhance selectivity by allowing oxidation on certain components of a transistor structure relative to passivated components (e.g., exposed metal-containing layers). Thus, in some embodiments, a passivation layer may be created prior to repeating a cycle of introducing 310 a pulse of an oxidizing agent and purging 330 for enhanced selectivity. In other embodiments, creation of a passivation layer may occur multiple times during the entirety repeated cycles of the cyclical oxidation process.

In another embodiment, the oxidizing agent is provided by adding O₂ gas to H₂, at a concentration below the explosion limit, which ratio the skilled artisan can calculate based on the desired temperature and pressure. In embodiments that use O₂ gas as an oxidizing agent, the O₂ gas concentration may be between about 0.00025% and about 4% by volume, as diluted in hydrogen, while in a preferred embodiment, the concentration will be between about 0.025% and about 2.5% by volume. The O₂ gas may be introduced into a chamber at a flow rate between about 2 sccm and about 800 sccm.

In accordance with FIG. 3, once the oxidizing agent has been introduced 310 for a specific period so as to allow oxidation on desired areas of a transistor gate structure, the oxidizing process may be stopped 320, such as by interrupting the flow of the oxidizing agent into the processing chamber while quickly purging 330 oxidant from the chamber with an inert or purge gas. The diffusion of oxidant into the gate stack layers of the transistor is reduced by stopping 320 and purging 340 the oxidizing agent. For example, with respect to FIG. 2, stopping the flow of an oxidizing agent can help to reduce the likelihood of oxidation occurring at the interface region 129 by limiting the number of oxygen atoms or molecules, or water molecules, that may diffuse to the region. In another embodiment, the flow of the oxidizing agent need not be stopped, but simply reduced, before or simultaneously with purging 330.

In accordance with FIG. 3, purging 330 may remove any remaining oxidizing agent. Purging 330 may remove most, but not necessarily all, of the remaining oxidizing agent. Various inert purging agents may be used, including N₂, Ar, He, H₂ and various combinations thereof.

In some embodiments, the purging agent will be introduced in a single wafer processing chamber. In other embodiments, the purging will occur in a batch processing chamber, having a capacity greater than 50 wafers, such as an ADVANCE® 412 vertical batch furnace, commercially available from ASM International, N.V. of Bilthoven, The Netherlands. In embodiments in which the purging occurs in a batch furnace, the purging agent will flow at a rate between about 1 and about 20 slm, while in a preferred embodiment, between about 5 and about 15 slm. In embodiments that use one or more purging agents, such as N₂ gas and H₂ gas in combination, the flow rate of each gas may vary from one another. There is generally no need to change temperature between the oxidation 310 and the purging 340 processes.

In some embodiments, purging 330 occurs long enough to remove most or all of the oxidant from the chamber or from the gate stack. In some embodiments, the purging 330 may last for a duration between two and twenty times the duration of a pulse of an oxidizing agent, such that the ratio of the purging period to the oxidation period in a single cycle of the cyclical oxidation process is between about 2:1 and about 20:1. In a preferred embodiment, purging 330 will occur for a duration between three and fifteen times the duration of a pulse of an oxidizing agent. Accordingly, a purging agent may be introduced as a pulse after an oxidation period for between about 6 seconds and about 6000 seconds.

In some embodiments, N₂ and/or Ar gas may be introduced into the chamber prior to a period of oxidation, such as during purging 330 from a prior cycle. The N₂ and/or Ar gas may be allowed to diffuse to surface interfaces, which may slow down the diffusion of oxygen atoms or molecules, or water molecules, to the interfaces during subsequent oxidation steps. The N₂ and/or Ar gas may be introduced concurrently with or separately from a different purging gas (e.g., H₂ vapor), or may serve as the purging gas, for a time between about 1 and about 10 minutes, to allow for the diffusion of atoms to the interface prior to oxidation. Each of the N₂ gas and the Ar gas may be introduced at a flow rate between about 1 and about 20 slm. In one embodiment, the N₂ and/or Ar gas is introduced before the first pulse of oxidation 310 (e.g., before the first selective oxidation cycle) is introduced.

In accordance with FIG. 3, introducing 310 an oxidizing agent, stopping 320 the flow of the oxidizing agent and purging 330 may be repeated 340 until oxidation of desired areas of the transistor structure is achieved. Thus, pulsing 310 of an oxidizing agent followed by purging 330 may be considered a cycle to be conducted two or more times as part of a cyclical oxidation process.

The cycle of introducing 310 an oxidizing agent and purging 330 may be repeated 340 a specific number of times until desired oxidation (for example, a certain thickness of silicon sidewall oxidation) is achieved. The number of times a cycle is repeated may be programmed in advance, or it may be determined by way of in situ metrology and closed loop control as the cyclical oxidation process proceeds. In some embodiments, the cycle of introducing 310 an oxidizing agent and purging 330 will occur between 1 and 10 times, more preferably between 3 and 6 times.

Throughout multiple cycles, the duration of each oxidation period and purging period may remain constant. For example, in one embodiment using H₂O water vapor as an oxidizing agent, the duration of each oxidation period (e.g., one pulse) may be about 20 seconds, with the purging period being a constant duration as well. In other embodiments, the duration of the oxidation, purging period, or both, may fluctuate over the course of multiple cycles. For example, in one embodiment using H₂O water vapor as an oxidizing agent, a first cycle may have a pulse of an oxidizing agent of about 20 seconds and a purging period of about 200 seconds, followed by a second cycle having a pulse of an oxidation for about 25 seconds and a purging period for about 250 seconds. Allowing the oxidation and purging periods to fluctuate per cycle, rather than remain constant, may allow for greater controllability of the oxidation process in some embodiments.

Regardless of the number of cycles used, a total oxidation time, which refers to the total time in which an oxidizing agent is introduced and excludes the purging periods, may be between about 1 and about 300 minutes. In a preferred embodiment, the total oxidation process will be between about 2 and about 240 minutes. The total time of oxidation may depend on multiple factors, including the type of oxidizing agent used and processing chamber conditions. The total time of oxidation may also depend on whether desired oxidation has been achieved on a specific surface, such as for repair of a dielectric at the gate corners. In some embodiments, an oxidation process will result in oxide thickness growth on silicon sidewall surfaces between about 10 and about 100 Å, while in a preferred embodiment, between about 20 and about 40 Å. In another embodiment, in which oxidation takes place for a total oxidation time of about 30 minutes in a chamber at about 750° C., an oxide layer may grow on an exposed silicon surface layer that is between about 20 and about 30 Å. In other embodiments wherein a transistor device stack includes at least one silicon containing layer, a cyclical oxidation process may result in a ratio of oxide growth at one interface of the silicon-containing layer to oxide growth at exposed silicon sidewalls of less than 0.1:1, such as between 0.001:1 and 0.1:1, or between 0.0001:1 and 0.1:1.

In some embodiments in which the cyclic oxidation process is selective, e.g., selective against metal-containing materials such as titanium nitride, a nitrogen source is flowed into the processing chamber during the selective oxidation process to enhance the overall selectivity of the oxidation process. In some embodiments, the nitrogen source is added during step 310, 320 and/or 330. In a preferred embodiment, the nitrogen source is introduced during step 310. Without being limited by theory, it is believed that enhanced selectivity results because the nitrogen source causes nitriding of the metal-containing material, which competes with oxidation on some components of the transistor device to guard against oxidation of that material.

The nitrogen source may be N₂, NH₃, N₂H₄ or combinations thereof. In some embodiments, the nitrogen source can form between about 10% and about 90% by volume, and more preferably, between about 40% and about 60% by volume of the gas flowing into the processing chamber. The nitrogen source may be introduced to a reactor environment separately or mixed with other sources. For example, in one embodiment in which a patterned transistor structure is provided having a TiN layer, N₂ gas may be introduced with H₂ gas, with the N₂ gas at about 50% by volume and H₂ gas at about 50% by volume, to enhance the selective oxidation process such that silicon is oxidized relative to the TiN layer during oxidation.

With continued reference to FIG. 3, in some embodiments, undesired oxidation may be prevented by introducing an oxygen scavenger into the processing chamber. The oxygen scavenger can be the same compound as the nitrogen source, or can be a different compound, which can be introduced in an oxidation process utilizing the nitrogen source or in an oxidation process in which the nitrogen source is not used. The oxygen scavenger can be introduced prior to, throughout or after the cyclic oxidation process, or at various steps during the cyclic deposition process. For example, the oxygen scavenger can be introduced during step 310 or 330.

The oxygen scavenger assists in preventing undesired oxidation by reacting with O₂ atoms to reduce the number of atoms available to oxidize exposed surfaces, such as exposed metal surfaces. The oxygen scavenger may react with any oxygen atom, regardless of whether the oxygen derives from an oxidation process or is naturally found in a chamber environment. For example, in one embodiment in which O₂ gas is provided as a combustible oxidizing agent in an H₂ environment to form H₂O water vapor, some O₂ gas may not combust, but rather, may oxidize exposed surfaces of a transistor structure. By providing an oxygen scavenger, the scavenger will react with the O₂ gas before the oxygen has an opportunity to react with the transistor structure.

Examples of suitable oxygen scavenging agents include, without limitation, hydrazine (N₂H₄), methylhydrazine (N₂H₄₋ₙ(CH₃)ₙ n−1-4), ethyl hydrazine (N₂H₄₋ₙ(C₂H₅)ₙ n=1-4), other organic hydrazines having carbon chains of 1 to 4 carbon atoms, saturated with hydrogen or one or more of the hydrogen atoms substituted by a halide and not containing oxygen, ammonia (NH₃) and any combination thereof. In some embodiments, the scavenging agent may be present in the processing chamber at a concentration of about 1% or more by volume. In other embodiments, the concentration is between about 0.1% and about 10% by volume. In one embodiment in which a transistor is provided having a TiN passivation layer, an oxygen scavenger (hydrazine) is present in the processing chamber at a concentration of about 1% by volume.

It will be appreciated that while the H₂ reacts with oxygen to form oxidizing H₂O water vapor, the oxygen scavenger, e.g., hydrazine, can react with the remaining O₂ particles to form N₂ and water, in some embodiments, thereby resulting in additional benefits. First, the number of oxygen atoms available to oxidize exposed surfaces and/or to diffuse to interfacial regions of the transistor structure is reduced by the hydrazine scavenger. Second, the formation of N₂ may react with the passivation layer, e.g., the TiN layer, and thereby improve the properties of the passivation layer, e.g., increasing the oxidation resistance of the passiviation layer.

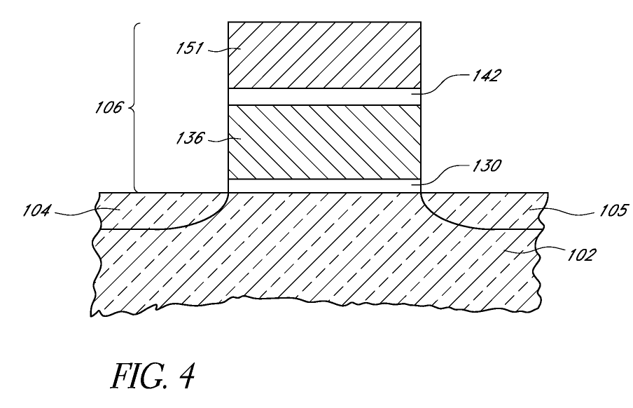

FIG. 4 is a schematic representation of a non-volatile memory device transistor structure having a patterned gate stack 106 comprising a control gate 151, an intergate dielectric 142, a floating gate 136, and a tunnel dielectric 130 above a substrate 102 having source 104 and drain 105 regions. Like the transistor structures shown in FIGS. 1A and 2, non-volatile memory device structures may also benefit from the cyclic oxidation methods described above.

FIG. 5 illustrates a more particular embodiment of a non-volatile memory device transistor structure comprising a patterned gate electrode structure 106 having an insulating cap layer 118, strapping metallic layer 165, conductive barrier 162, control gate 151, intergate dielectric 142, a floating gate 136 and a tunnel dielectric 130 over a substrate 102. One skilled in the art will appreciate that various combinations of layers composed of many different materials, besides those shown in FIG. 5, may be used and subject to the oxidation processes described herein. Aside from the specific transistor layers, areas of undesired oxide formation or oxide thickness increase 196 are also illustrated, as well as areas 198 where oxidation is acceptable.

The embodiment in FIG. 5 illustrates a strapping metal layer 165, which serves as a conductive interconnect layer, beneath the cap layer 118. Although the strapping metal layer 165 is depicted in FIG. 5 as being tungsten, other metals suitable for high conductivity may also be used. Beneath the strapping metal layer 165 is a conductive barrier 162 comprising tungsten nitride. Under the conductive barrier is a control gate 151 comprising polysilicon, which is adjacent to an intergate dielectric 142. The illustrated intergate dielectric 142 comprises a first oxide layer 143, a nitride layer 144 and a second oxide layer 145, commonly referred to by those skilled in the art as an “ONO” layer. Charges and data may be stored on the ONO intergate dielectric layer, and it is thus important to control its properties. On the other side of the intergate dielectric 142 is a floating gate 136, which is also composed of polysilicon.

The floating gate 136 rests above the tunnel oxide 130, which may be formed over a semiconductor layer (not shown). Tunnel oxides are generally about 50 to 100 Å thick. In non-volatile memory devices, programming and erasing functions occur due to charge transfer processes across the tunnel oxide layer. It is thus important to control properties of the tunnel to ensure the ability to read and write by tunneling, and the cyclic oxidation processes of the present application may help to repair damaged tunnel areas at the corners, to prevent data loss caused by charge trapping areas and leakage, while minimizing thickness increases in the middle of the tunnel dielectric 130.

The cyclic oxidation process of the present application may be particularly beneficial to prevent the growth of areas of undesired oxide formation or oxide thickness increase 196 within the transistor gate stack 106. FIG. 5 illustrates four specific interfacial areas 196 prone to undesired oxide formation or growth may occur. These areas may be subject to excessive oxide growth due to the diffusion of oxidants along interfaces and/or dielectrics to reach and oxidize surfaces of adjacent conductors (e.g., the polysilicon control gate 151 and/or polysilicon floating gate 136), often due to the availability of silicon, during an oxidation process. While use of a selective chemistry and/or surface passivation can reduce susceptibility of external surfaces of metallic layers to oxidation, the interfaces are not so protected. Using a relatively short pulse of an oxidizing agent followed by a purging process, according to the cyclic oxidation methods described herein, helps to reduce such oxidant diffusion across transistor layers, and thus, prevents excessive oxide thickening at gate stack interfaces.

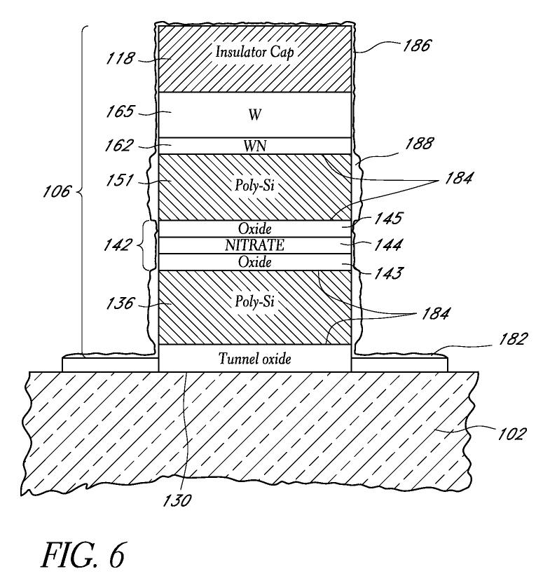

FIG. 6 illustrates a cross-sectional representation of the gate electrode structure 106 of FIG. 5 after a cyclic oxidation process according to one embodiment has occurred. Applying a cyclic oxidation process as described above (e.g., introducing a pulse of an oxidizing agent followed by a pulse of a purging agent) can result on some exposed surfaces of the transistor having moderate oxide formation 188, such as on polysilicon sidewalls, while minimal (if any) oxide formation 186 on other areas. In some embodiments, metallic surfaces may be protected by a passivation layer and/or selective chemistry, whereas dielectric-electrode interfaces are protected by the cyclical process, inhibiting oxidant diffusion into the gate stack 106. Oxidation on some areas of the transistor device may be desired, such as at the corners 130 of the tunnel oxide 182, which may need to be repaired after an etching process. In some embodiments, and as shown in FIG. 6, the oxidation process of the present application will result in no appreciable oxide formation 184 at the interfacial regions that may be prone to undesired oxide formation due to diffusion.

### EXAMPLE 1

In one embodiment of a cyclic oxidation process, a pulse of an oxidizing agent is introduced comprising H₂O water vapor diluted in an H₂ environment, wherein the H₂O water vapor is 15% by volume. The oxidation takes place at a temperature of 750° C. in a batch furnace. A pulse of the H₂O water vapor is introduced at a flow rate of 3 slm for 120 seconds before being stopped. After or simultaneously with stopping the flow of the oxidizing agent, a pulse of a purging agent comprising 100% by volume H₂ gas is introduced to remove any remaining oxidizing agent. The H₂ gas is introduced at a flow rate of 17 slm. The purging will have a duration ten times the duration of the pulse of the oxidizing agent, or 1200 seconds. The cycle of introducing an oxidizing agent followed by a purging agent may be repeated 15 times, such that the total oxidation period is 1800 seconds, resulting in an oxide growth on an exposed silicon surface of 25 Å.

### EXAMPLE 2

In another embodiment of a cyclic oxidation process, a pulse of an oxidizing agent is introduced comprising 8% by volume H2O water vapor in an H₂ environment. The oxidation takes place at a temperature of 850° C. in a batch furnace. A pulse of the H₂O water vapor is introduced at a flow rate of 1.5 slm for 20 seconds before being stopped. After stopping the flow of the oxidizing agent, a pulse of a purging agent comprising 100% by volume H₂ gas is introduced to remove any remaining oxidizing agent. The H₂ gas is introduced at a flow rate of 8.5 slm. The purging will have a duration ten times the duration of the pulse of the oxidizing agent, or 200 seconds. The cycle of introducing an oxidizing agent followed by a purging agent may be repeated 15 times, such that the total oxidation period is 300 seconds, resulting in an oxide growth on a silicon sidewall surface of 20 Å.

### EXAMPLE 3

In another embodiment of a cyclic oxidation process, a pulse of an oxidizing agent is introduced comprising 4% by volume O₂ gas in an H₂ environment. The oxidation takes place at a temperature of 850° C. in a batch furnace. A pulse of the O₂ gas is introduced at a flow rate of 0.8 slm for 20 seconds before being stopped. After stopping the flow of the oxidizing agent, a pulse of a purging agent comprising 100% by volume H₂ gas is introduced to remove any remaining oxidizing agent. The H₂ gas is introduced at a flow rate of 19.2 slm. The purging will have a duration ten times the duration of the pulse of the oxidizing agent, or 200 seconds. The cycle of introducing an oxidizing agent followed by a purging agent may be repeated 15 times, such that the total oxidation period is 300 seconds, resulting in an oxide growth on a silicon sidewall surface of 20 Å.

### EXAMPLE 4

In another embodiment of a cyclic oxidation process, a pulse of an oxidizing agent is introduced comprising H₂O water vapor diluted in an H₂ environment, wherein the H₂O water vapor is 15% by volume. The oxidation takes place at a temperature of 750° C. in a batch furnace. A pulse of the H₂O water vapor is introduced at a flow rate of 3 slm for 120 seconds before being stopped. After stopping the flow of the oxidizing agent, a pulse of a purging agent comprising H₂ gas is simultaneously introduced with N₂ gas. The H₂ gas with Ar and/or N₂ gas are introduced at flow rates of about 18 slm and 2 slm, respectively. Initially, the H₂ gas comprises a large volume percentage early in the purging (e.g., greater than 80% by volume), while the Ar and/or N₂ gas comprises a small volume percentage (e.g., less than 20% by volume), during the first 60 seconds of purging. After 60 seconds, the flow rate of the of the H₂ gas is ramped down to 1 slm while the flow rate of the Ar and/or N₂ gas is ramped up to 19 slm, such that the H₂ gas is largely replaced by the Ar and/or N₂ gas. The purging with H₂ gas will have a duration ten times the duration of the pulse of the oxidizing agent, or 1200 seconds. In the last 60 seconds of the purge period, the H₂ gas flow is ramped back up, while the Ar and/or N₂ is ramped back down, so that the purge gases return to their values at the beginning of the purge period, thereby ensuring a selective regime when H₂O is present in the processing chamber. The cycle of introducing an oxidizing agent followed by a purging agent may be repeated 15 times, such that the total oxidation period is 1800 seconds, resulting in an oxide growth on an exposed silicon surface of 25 Å.

It will be apparent to those skilled in the art that various modifications and variations can be made in the present invention without departing from the scope or spirit of the invention. Thus, it is intended that the present invention cover the modifications and variations of this invention provided that they come within the scope of the appended claims or their equivalents.

What is claimed is:

1. A method of selective oxidation, comprising:
providing a transistor structure having exposed silicon and metal, wherein the transistor structure comprises a patterned gate stack having a gate electrode and a dielectric layer;
introducing a pulse of an oxidizing agent to the transistor structure, such that the silicon is oxidized relative to the metal;
purging to remove the oxidizing agent; and
repeating introducing a pulse of the oxidizing agent and purging.

2. The method of claim 1, wherein the gate stack includes the metal.

3. The method of claim 1, wherein providing the gate stack comprises providing a floating gate below the gate electrode and above a tunnel dielectric.

4. The method of claim 1, wherein at least one of the provided dielectric layers comprises an intergate dielectric comprising a first oxide layer, a nitride layer and a second oxide layer.

5. The method of claim 1, wherein the oxidizing agent comprises H₂O water vapor diluted in H₂ gas, the H₂O water vapor being between about 0.0005% and about 20% by volume.

6. The method of claim 5, wherein the H₂O water vapor is introduced at a flow rate between 2 sccm and 4 slm.

7. The method of claim 1, wherein the oxidizing agent comprises O₂ gas in H₂ gas, the percent of O₂ gas in H₂ gas being between 0.00025 and 4%.

8. The method of claim 7, wherein the O₂ gas is introduced at a flow rate between 2 sccm and 800 sccm.

9. The method of claim 1, wherein the oxidizing agent is introduced at a temperature of between 550 and 900 degrees Celsius.

10. The method of claim 1, wherein purging comprises flowing H₂ gas.

11. The method of claim 1, wherein the pulse of an oxidizing agent is introduced for between 5 and 30 seconds.

12. The method of claim 1, wherein purging is conducted for between five and fifteen times the duration of the pulse of the oxidizing agent.

13. The method of claim 1, wherein introducing a pulse of the oxidizing agent and purging is repeated such that the total period of oxidation by the oxidizing agent is between three and seven minutes.

14. The method of claim 1, wherein providing the gate stack includes providing at least one silicon containing layer and the method oxidizes such that the ratio of oxide growth at the interface of the silicon containing layer to oxide growth at the exposed sidewalls of the silicon containing layer is between 0.0001:1 and 0.1:1.

15. A method of performing oxidation on a patterned transistor gate stack, comprising:
providing a patterned transistor gate stack;
introducing a pulse of an oxidizing agent to the patterned transistor gate stack;
purging the oxidizing agent for a duration between three and fifteen times the duration of the pulse of the oxidizing agent to remove the oxidizing agent; and
repeating the steps of introducing a pulse of an oxidizing agent and purging.

16. The method of claim 15, wherein the duration of introducing a pulse of an oxidizing agent remains constant throughout the total oxidation process.

17. The method of claim 15, further comprising introducing N₂ or Ar to the patterned transistor gate stack prior to introducing the oxidizing agent.

18. The method of claim 15, wherein the oxidizing agent is introduced selectively such that silicon is selectively oxidized relative to metal.

19. The method of claim 15, wherein repeating is conducted 2 to 20 times.

20. The method of claim 15, further comprising introducing a passivation layer to the gate stack before introducing a pulse of an oxidizing agent.

21. A method of performing oxidation on a transistor gate stack, comprising:
providing the transistor gate stack on a substrate in a processing chamber;
performing a plurality of oxidation cycles, each cycle comprising:
introducing an oxidizing agent into the processing chamber to oxidize at least some portion of the gate stack;
providing an oxygen scavenger in the processing chamber; and
removing the oxidizing agent from the processing chamber.

22. The method of claim 21, wherein the steps of introducing the oxidizing agent, providing the oxygen scavenger, and removing the oxidizing agent are repeated in sequence.

23. The method of claim 21, wherein the oxygen scavenger is selected from the group consisting of hydrazine; methylhydrazine; ethylhydrazine; other organic hydrazines having carbon chains of 1 to 4 carbon atoms, saturated with hydrogen or one or more of the hydrogen atoms substituted by a halide and not containing oxygen; ammonia; and combinations thereof.

24. The method of claim 23, wherein the oxygen scavenger is introduced at a flow rate of between 20 sccm and 2 slm.

25. The method of claim 21, wherein the oxygen scavenger is present at a concentration of between about 0.1 and about 10% by volume during providing the oxygen scavenger.

26. The method of claim 21, wherein the steps of introducing the oxidizing agent and providing the oxygen scavenger at least partially overlap in time.

27. The method of claim 21, wherein introducing the oxidizing agent comprises flowing O₂ gas and H₂ gas into the processing chamber and allowing the O₂ gas and H₂ gas to form H₂O, wherein H₂O is the oxidizing agent.

28. The method of claim 21, wherein the oxygen scavenger reacts with O₂ gas to form H₂O water vapor and N₂ gas.
